(19) United States
(12) Patent Application Publication
(10) Pub. No.: US 2011/0168227 A1
(43) Pub. Date: Jul. 14, 2011

(54) SINGLE FACE CORRUGATED PLASTIC OR ALUMINUM SOLAR COLLECTOR

(76) Inventor: Robert Wilfrid Carriere, Hamilton (CA)

(21) Appl. No.: 12/987,124

(22) Filed: Jan. 9, 2011

Related U.S. Application Data
(60) Provisional application No. 61/293,641, filed on Jan. 9, 2010.

(51) Int. Cl. H01L 31/042; F24J 2/04

(52) U.S. Cl. 136/244; 126/647

(57) ABSTRACT

The present invention is a single face corrugated plastic solar collector. The invention incorporates an air flow with a unique cross-over pattern to maximize surface coverage. The solar collector creates energy by forcing air through a single-sided corrugated plastic or aluminum sheet, which is exposed to the sun for the purpose of heating buildings, appliances, pools and other areas and equipment. Air flow is initially powered by multiple photovoltaic cell powered blower motors to maximize aft flow with minimal air pressure. Air volume is kept high within the corrugated plastic with minimal pressure verses atmospheric pressure to seal the aft within the area of the corrugations. The solar collector allows for maximum solar coverage, low cost per square foot coverage, ease of shipping and simplicity of installation.

This application claims priority to Provisional Application 61/293,641 filed on Jan. 9, 2010, the entire disclosure of which is incorporated by reference.

### TECHNICAL FIELD & BACKGROUND

There are basically three types of solar heating systems today available on the market. The first system involves photovoltaic cells that convert sunlight to electricity via a silicon reaction. This system has high potential for the future with numerous applications. At the present time, homes that use this type of solar system are still expensive, with a typical mass-produced system still costing $40.00 per square foot. Installation requires electricians, structural advisers or architects making installation expensive, which results often in a $50,000 dollar home owner investment for a return of $1,000 per year in energy savings. The second type of solar heating system involves parabolic mirrors that are computer controlled to utilize an accurate focal point of the sun to superheat water resulting in steam generated electricity. This type of system has limited use at this time and is primarily confined to commercial and government experimental projects. The third type of system is a hydro-thermo system that sits in the sun and transfers the sun's heat into water through a circulation pump. These are medium cost systems that use copper tubing and extruded tubular plastic sheets to circulate water in sunlight to heat pools or hot water tanks. Installation for this type of system requires electricians, plumbers and structural engineers and a complete system typically cost $20,000 per installation. Since this system is limited in energy usage, the return on investment is about $500.00 per year at best. All 3 systems require professional installation crews and regular maintenance.

What the market really needs is a solar collector that has a positive return on investment within three years. It may be great to be green and save the planet however it must also be affordable and worthwhile. The solar panel hot air heater achieves this by maximizing efficiency, simplicity of installation and low initial cost with no maintenance.

The invention relates to the design of a solar collector that has a very positive return on investment. All existing green energy systems tend to have a large initial cost and require professional installation. The net result is that most other green and solar systems are limited to utilities or government institutions. This solar heater design is affordable, shippable, can easily be installed and delivers sufficient energy to pay for itself in less than a couple years.

The method used is to take advantage of low cost single-faced corrugated plastic or aluminum. Single-faced corrugated plastic or aluminum already has the solar advantage of maximum surface area by virtue of the corrugation. The sealed solar collector also facilitates air flow within the corrugation to extract heat. The invention incorporates photovoltaic cell powered blower units to create and maintain air flow in an interlaced pattern within the corrugations. This self-powering solar collector then delivers hot air to modified clothes dryers, pre-heat fresh air intake to furnace, swimming pools, heat pumps, direct heat for buildings and other self-powered solar heater settings.

### BRIEF DESCRIPTION OF THE DRAWINGS

The present invention will be described by way of exemplary embodiments, but not limitations, illustrated in the accompanying drawings in which like references denote similar elements, and in which:

FIG. 1 illustrates an environmental perspective view of a house incorporating the single-side corrugated solar collector system, in accordance with one embodiment of the present invention.

FIG. 2 illustrates an overhead perspective view of a single-side corrugated plastic or aluminum sheet rolled out using a standoff anchor, deflection brackets and blower brackets, in accordance with one embodiment of the present invention.

FIG. 3 illustrates a cut away top side perspective view of a blower bracket with deflection brackets in combination with the single-side corrugated plastic sheet, in accordance with one embodiment of the present invention.

FIG. 4 illustrates a cut away top side perspective view of a deflection bracket that utilizes a cut-out exposing seal tooth method, in accordance with one embodiment of the present invention.

FIG. 5 illustrates a side perspective view of a blower bracket exposing the interior seals and motors of a fan, in accordance with one embodiment of the present invention.

FIG. 6 illustrates a top side perspective view of an assembled redirection blower bracket with photovoltaic panels, in accordance with one embodiment of the present invention.

FIG. 7 illustrates a side perspective view of a corrugated plastic or aluminum sheet, deflection brackets and a clear plastic cover sheet windshield, in accordance with one embodiment of the present invention.

FIG. 8 illustrates a top side perspective view of a stand-off anchor used in combination with a single faced corrugated plastic or aluminum solar collector, in accordance with one embodiment of the present invention.

FIG. 9 illustrates a diagonal side perspective view of a clothes dryer cover for the air intake of a single faced corrugated plastic or aluminum solar collector, in accordance with one embodiment of the present invention.

FIG. 10 illustrates a cut away top side perspective view of an aeration unit used in combination with a single faced corrugated plastic or aluminum solar collector, in accordance with one embodiment of the present invention.

FIG. 11 illustrates a diagonal side perspective view of a duct work booster fan used in combination with a single faced corrugated plastic or aluminum solar collector, to pre-heat fresh air intake or heat building, in accordance with one embodiment of the present invention.

FIG. 12 illustrates a diagonal perspective view of an aluminum version of the corrugated solar collector and how the aluminum corrugations and closed cell foam base, are uniquely assembled to achieve a greater efficiency per square foot, in accordance with one embodiment of the present invention.

### DETAILED DESCRIPTION OF ILLUSTRATIVE EMBODIMENTS

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention. However, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

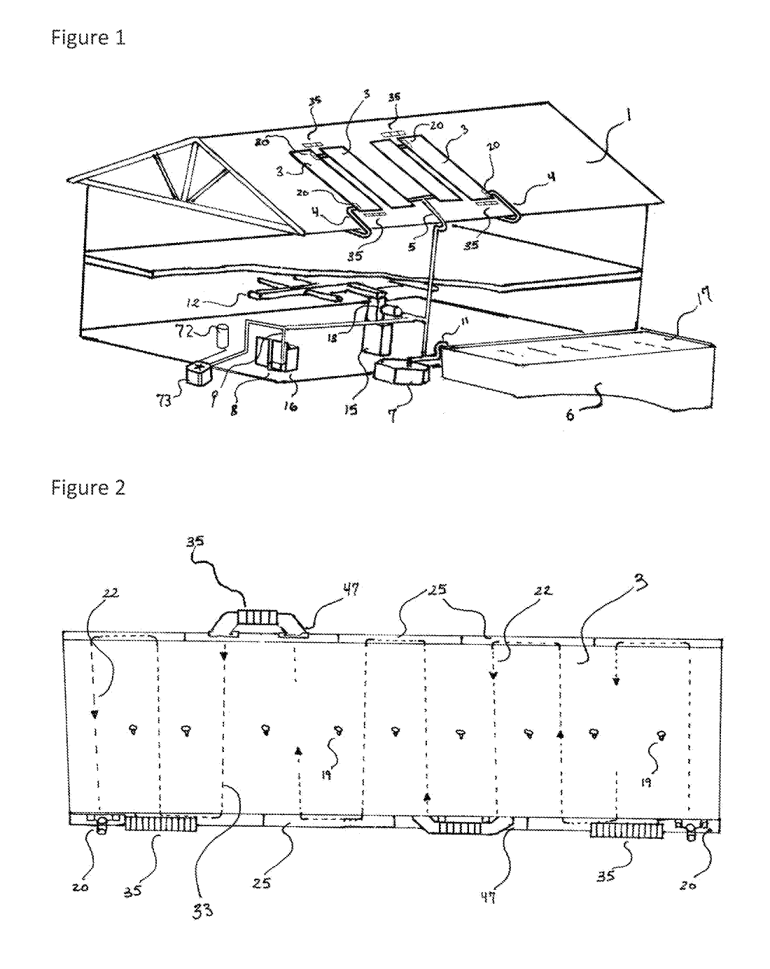

FIG. 1 illustrates an environmental perspective view of a house (1) with single-faced corrugated solar collectors (3) on the roof of the house (2), in accordance with one embodiment of the present invention. These solar collectors (3) are in a series and/or parallel configuration. The design advantage of the single-faced corrugated solar collectors (3) is that they have multiple possible configurations in series, in parallel or in series and parallel of varying lengths. In northern climates, a continuous solar collector (3) has a distinct advantage of having an accumulated temperature increase. The intake air (4) is recommended to be sourced from the highest ceiling for maximum efficiency, though fresh outside air or other sources are acceptable. The intake air (4) enters via a blower assembly (20) that is powered by photovoltaic cells (34) and circulates through the singled-faced corrugated solar collector (3) where it gets heated by the sun and exits as exhaust air (5). The exhaust air (5) then travels via distribution tubing (14) where it is distributed for use. The tubing (14) is recommended to travel to the duct booster assembly (13). The duct booster assembly (13) is electrically connected to the household electrical system. The duct booster assembly (13) uses the extra power advantage of the household electrical system that can push a high volume of air throughout the house (1) via the duct work (12), supplementing the furnace (15) by pre-heating the fresh air intake.

The exhaust air (5) may also travel via the tubing (14) to a clothes dryer (8), where a custom dryer cover (16) creates a closed air intake to the dryer (8). The advantage is the hot air from the solar collector (3) is the primary source of heat for drying clothes. Simply placing the dryer (8) on air dry during sunny days will result in the dryer (8) utilizing the existing blower motor (21) to boost the solar collector (3) and the exhaust air (5) through the dryer (8). The exhaust air (5) may also be directed via tubing (14) to a swimming pool (6) and a hot tub (7), where the exhaust air (5) is simply blown into the water (17) through aeration to heat the pool (6) or the hot tub (7).

The exhaust from the solar collector (3) can also supplement the operation of heat pump (73). In much colder temperatures heat pumps (73) become very inefficient. At temperatures above freezing the heat pump (73) can have 300 percent efficiency. However, the lower the outside ambient temperature reaches the lower the efficiency of the heat pump (73). The result will eventually enter the negative in efficiency range.

By marrying the two technologies the solar collector (3) can raise the outside ambient air temperature from well below freezing to a level above freezing, whereupon the heat pumps efficiency can raise the temperature to greater levels required for a hot water tank (72), or for any other requirement.

FIG. 2 illustrates an overhead view of a solar collector (3) with a criss-cross air flow pattern (22), in accordance with one embodiment of the present invention. The solar collector (3) is assembled with the positioning of the first blower motor (21) at the front of the criss-cross pattern (22). The air crosses the individual corrugations (30) to the opposite side of the solar collector (3). On the opposite side of the solar collector (3), air flow is redirected through a redirection bracket (25) where air flow crosses back over across the solar collector (3). Air flow reaches the opposite side and is again redirected via a redirection bracket (25) and crosses over again and is again redirected via redirection bracket (25). Eventually, the air flow and air pressure diminishes due to resistance and friction. Redirection booster blowers (47) can increase air flow and pressure at regular intervals. These redirection blowers (47) suck air in as well as push air outward. By positioning the redirection blowers (47) at the criss-cross pattern (22), the air flow remains maximized at minimal pressure. By maintaining maximum air flow volume at the criss-cross pattern (22), there is an efficiency gain as the internal air flow is forced to cover every square inch of the solar collector for full heat transfer from individual corrugations (30).

The blower assembly (20) completes the air flow at the solar collector (3) by giving solar heated air a final push towards another solar collector (3) to exit as exhaust air (5). The blower assembly (20) is powered by photovoltaic cells (34). This is a passive system that powers air flow automatically as the sun's rays hit the photovoltaic cells (34) and solar collector (3) in unison. The advantage is that the installation and future maintenance omits any external power source or sensor system. Research has discovered that, as you approach the polar areas of the earth, the sun's angle striking the earth, is reduced substantially, especially during the winter solstice. The result is that the material of the solar collector (3), even at high noon with no air flow, is reduced in temperature. However the design of the solar panel (3) with its criss-cross pattern, actually accumulates heat as air moves across the solar collector (3). The result is that air flow on a sixty foot long panel has actually travelled 240 feet and has been found to have a resulting increase in exit temperature of twenty percent more than the solar collector's (3) inert temperature. This is an advantage that can be accessed by configuring the solar collector (3) for maximum air flow distance. At the equator, the solar collector (3) should be configured and combined in parallel. The result is that you still have air volume and surface coverage, but not the extreme temperature that may result in loss of material integrity and/or safety.

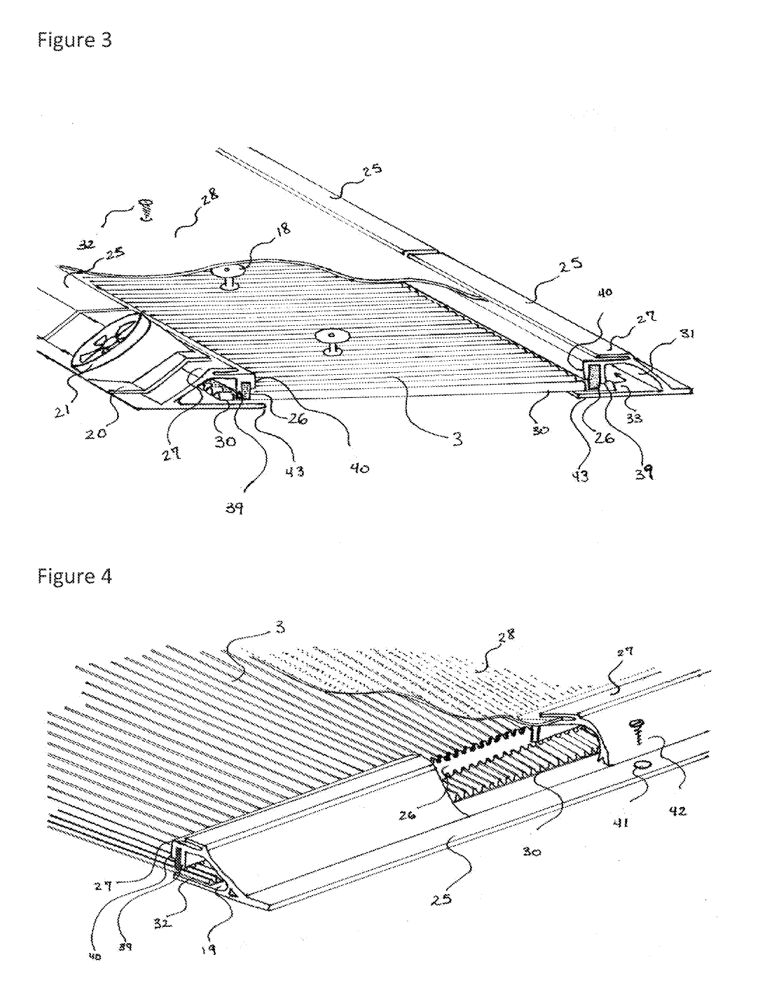

FIG. 3 illustrates a cut away top side perspective view of the solar collector (3), in accordance with one embodiment of the present invention. It has on one side a view of a blower assembly (20) and on the opposite side a cross-sectional view of a redirection bracket (25). Air is powered through the blower assembly (20) and fills the bracket air cavity (31) with air. The air is then defused via a series of individual corrugations (30) and crosses over to the directional bracket (25). The air flows into the bracket air cavity (31) of the re-directional bracket (25) and air flow passes down the bracket air cavity (31) where the second half of the bracket air cavity (31) forces the air through an opposing series of individual corrugations (30) back across the solar collector (3). To enclose the solar collector (3), a clear plastic sheet windshield (28) covers and encloses the individual corrugations (30). This boxing effect of the windshield (28) creates a closed environment that insulates the individual corrugations (30) from any wind robbing effect. The windshield (28) is anchored to the solar collector (3) via a standoff fastener (18). The standoff fastener (18) anchors the solar collector (3) to the roof (2) at the center of the solar collector (3). This allows the individual corrugations (30) to expand into the redirection brackets (25) during hot sunny days and contract on cool nights. The stand-off fastener (18) then supports the windshield (28). The windshield (28) is fastened to the stand-off fastener (18) via a windshield fastener (32). The windshield (28), by being anchored in the center can also expand outward to the redirection brackets (25) by a retaining lip (27) that secures the edges of the outside edge of the windshield (28). This still allows movement for expansion and contraction within the retaining lip (27). The center standoff fastener (18) keeps the windshield (28) from waving, buckling and breaking due to material movement. Any waving or buckling would compromise the solar collector's (3) air seal.

The individual corrugations (30) move in and out of the redirection brackets (25) while maintaining a constant seal of air within the bracket air cavity (31). The seal is maintained by a corrugated tooth seal (26) that is shaped to match the individual corrugations (30). The pressure of the corrugated tooth seal (26) against the individual corrugations (30) is sufficient to maintain air pressure within the bracket air cavity (31). The individual corrugations (30), however, still have enough room to expand and contract. This corrugated tooth seal (26) provides for internal air pressure within the individual corrugations (30) and the bracket air cavities (31) are maintained within seven pounds per square inch of atmospheric pressure even though the individual corrugations (30) expand and contract. This design is required to maintain internal air integrity within solar collector (3) sizes that can exceed 50 feet or more. The cross-section of the redirection bracket (25) has sandwiched the corrugated tooth seal (26) between an inside tooth seal support (39) and an outside tooth seal support (40). When the end user or installer combines the closed corrugated tooth seal (26) with a silicon sealer to create a flexible bond between the closed corrugated tooth seal (26) and the individual corrugations (30), a sufficient air seal is created. Even over a distance of 50 feet or more, the redirection brackets (25), the corrugated tooth seal (26) and the individual corrugations (32) work in combination to keep hot solar heated air within the bracket air cavity (31).

The blower assembly (20) is designed in combination with the redirection bracket (25) with the added feature of a blower motor (21) that is powered by photovoltaic cells (34). These blower motors (21) initiate air flow through the bracket air cavities (31) and individual corrugations (30). The air flow is subsequently boosted at sufficient intervals by succeeding blower motors (21) in order to maintain maximum air flow with minimal pressure. In the cross-section of the redirection bracket (25), it can be seen that the corrugated tooth seals (26) are held in place by an inside corrugated tooth support (39) and by an outside corrugated tooth support (40). It is noted that the outside tooth support (40) is designed shorter to allow for insertion of the closed corrugated tooth seals (26). The outside tooth support (40) is extended longer to create a stronger support possible for the corrugated tooth seal (26). The redirection bracket (25) also has an outside tooth support (40) in order to facilitate and simplify the insertion of the redirection bracket (25) into the individual corrugations (30) during assembly. The bracket base extension (43) supports the individual corrugations (30) while pressure is applied upward to the redirection bracket (25) opening the corrugated tooth seal (26) for easy insertion of the individual corrugations (30). Releasing the upward pressure on the redirection bracket (25) also creates a spring tight pressure seal.

FIG. 4 illustrates a cut away top side perspective view of a redirection bracket (25) that has a cut-out exposing the closed corrugated tooth seal (26), in accordance with one embodiment of the present invention. The corrugated tooth seal (26) is precisely patterned to match the individual corrugations (30) for maximum seal. To accommodate future maintenance and wear and tear, the corrugated tooth seal (26) has teeth on both sides. The corrugated tooth seal (26) can also be removed and reinserted upside down to form and secure a new seal. The individual corrugations (30) are exposed to any air flow and the redirection bracket (25) has a bracket anchor (41) that is secured with a plurality of bracket anchor screws (42).

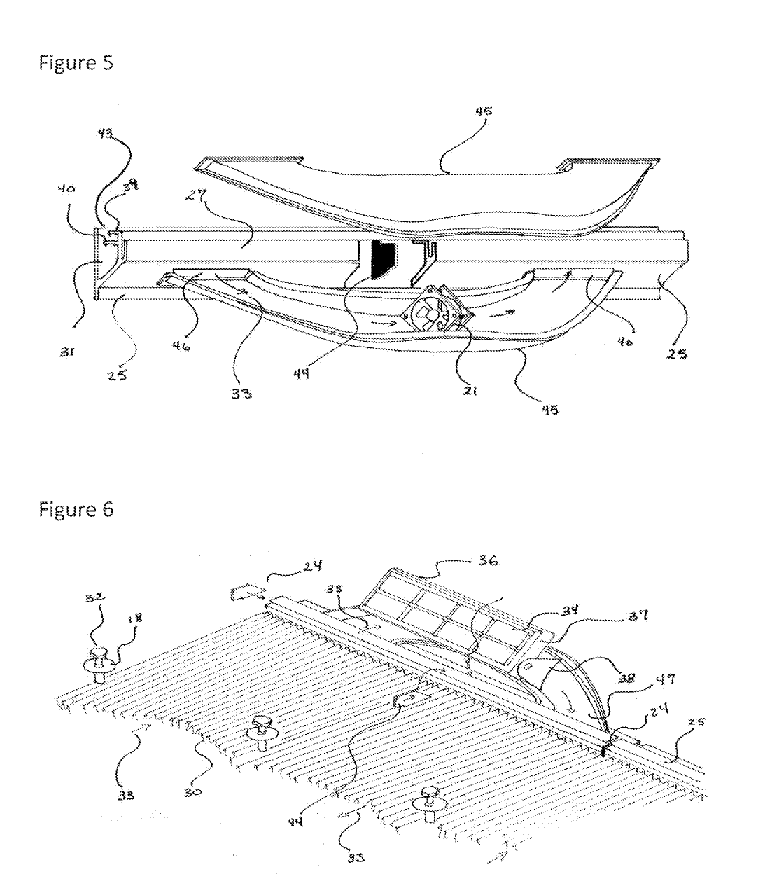

FIG. 5 illustrates a side perspective view of the blower assembly (20), in accordance with one embodiment of the present invention. The blower assembly (20) includes a redirection bracket (25) with blower enclosure cut-outs (46) on either side. Near the blower enclosure cut-out (46) in the center of the directional bracket (25) is a redirection bracket seal (44) that stops air flow through the bracket air cavity (31). With the bracket air cavity (31) sealed, the air is redirected through the blower enclosure cut-outs (46) and enters the blower cover (45). For the purpose of better understanding, the blower cover (45) is divided into its two halves. This view exposes the blower motor (21) that is sealed inside with the air flow (33) clearly indicating the function of the blower motor (21).

FIG. 6 illustrates a top side perspective view of a blower assembly (20), following the air flow (33) passing through the individual corrugations (30) and entering the redirection bracket (25), in accordance with one embodiment of the present invention. The air is drawn into the redirection blower assembly (47) and into the blower motor (21). The blower motor (21) also pushes air forward through the opposite side of the redirection bracket (25). A rubberized air seal (44) is drawn on the outside of the redirection bracket (25) with arrows indicating its intended location. There are also expansion end seals (24) that are positioned between the redirection brackets (25) to absorb any linear expansion of redirection bracket (25). The redirection brackets (25) are anchored via bracket anchor screws (42) in the center of the redirection bracket (25). This way the redirection brackets (25) expand outward from the center into the expansion end seals (24). This avoids an accumulation of expansion of redirection bracket (25) which may easily add unwanted length. There is also a photovoltaic cell assembly (36) which is an accumulation of photovoltaic cells (34) attached to a solstice adjustment hinge (38). The solstice hinge (38) makes adjustments to the photovoltaic cells (34) according to the sun's angle during the different solstice cycles.

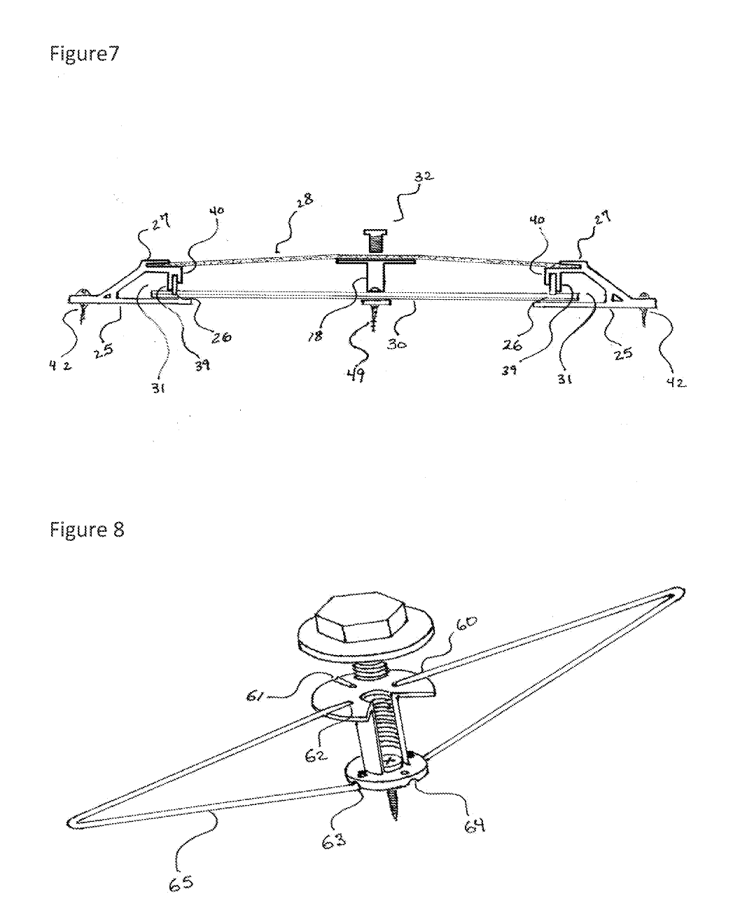

FIG. 7 is a cross-sectional view of a solar collector (3) on both sides of a directional bracket (25), in accordance with one embodiment of the present invention. FIG. 7 illustrates the attachment method of the individual corrugations (30) and the attachment of the windshield (28) to the directional brackets (25). The individual corrugations (30) are held via the corrugated tooth seal (26) using the pressure of the directional bracket (25). The tooth seal (26) is supported by an inside tooth seal support (39) and an outside tooth seal support (40). The windshield (28) is held to the directional brackets (25) via a retaining bracket lip (27). This retaining bracket lip (27) holds the windshield (28) securely and still provides for expansion and contraction. There is also a standoff anchor (18) which has an internal screw (49) that anchors to the base of the stand-off anchor (18), sandwiching the individual corrugations (30) to a given attachment surface. The windshield (28) is then fastened by a screw (32) into the standoff anchor (18). The complete solar collector (3) is anchored to the roof (2) or surface area by bracket anchor screws (42) at the base of the standoff anchor (18).

FIG. 8 illustrates a top side perspective view of a unique standoff anchor (18) that allows an installer to sandwich two separate layers together without having access to a previous layer, in accordance with one embodiment of the present invention. Existing anchor technology requires access to a first layer from above or below the layer in some way or another. By having the standoff anchor (18) fastener inside, the installer can install the standoff anchor (18) more easily. The process begins by screwing the standoff anchor (18) and the individual corrugation (30) into the roof (2) or surface area using an internal 20 anchor screw (49). The stand-off anchor (18) accommodates the windshield (28) and the windshield fastener (32). Without any effort, the windshield fastener (32) can be threaded into the stand-off anchor (18) to secure the windshield (28). A standoff anchor indent (48) is placed in the individual corrugation (30) to precisely position the stand-off anchor (18).

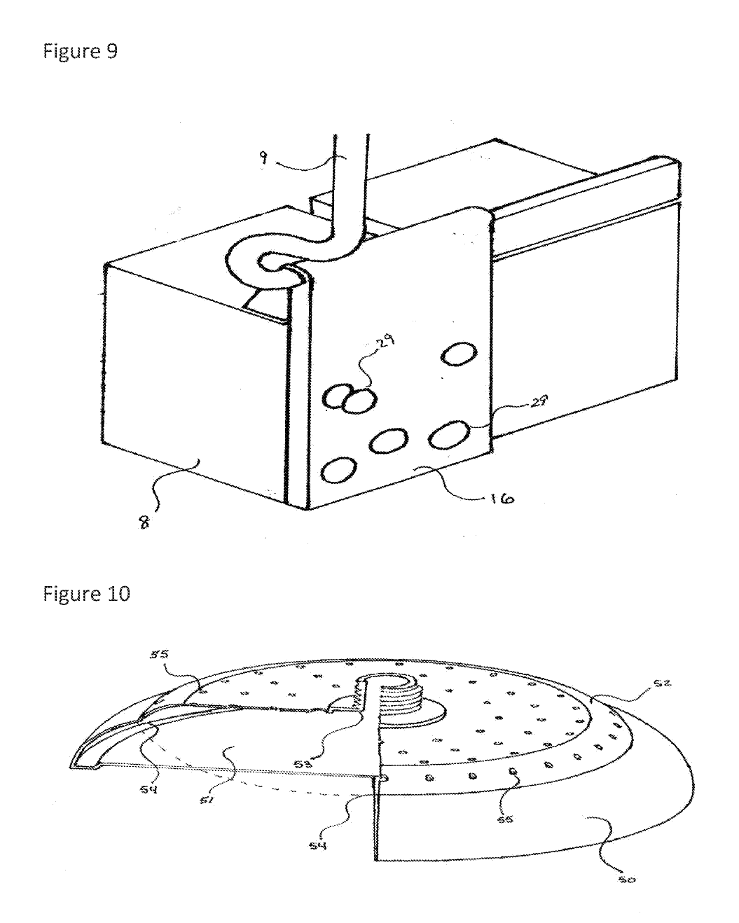

FIG. 9 illustrates a diagonal side perspective view of a clothes dryer cover (16) that can direct solar heated air from the solar collector (3) by a dryer tube (9) into the dryer air intake, in accordance with one embodiment of the present invention. The clothes dryer (8) typically uses an electric element or gas burner to heat air and dry clothes. The clothes dryer (8) also has the option of air drying without using any electric or gas heat. By placing the clothes dryer (8) in air dry mode on a sunny day, the clothes dryer (8) would automatically take advantage of the heated solar air to dry clothes. A gained advantage is that the clothes dryer (8) has its own built-in air blower that will boost the air volume and pressure. The clothes dryer cover (16) also has dryer cover imprints (29) at appropriate locations to mark any dryer exhaust depending on machine and model.

To further strengthen the windshield (28) a hard wire truss (65) is connected to the standoff anchor (19). The method for connecting the hard wire truss (65) to the standoff anchor (19) is by creating a spring effect that holds the truss (65) at the top of the standoff anchor (60) and at the bottom of the standoff anchor (64). The standoff anchor (18) has a hole (62) by which the truss is inserted to lock it into position and a groove (61) is formed into the top of the standoff anchor (60) to guide the direction of the truss. The resulting sandwiching of the standoff anchor (18), truss (65) and corrugations (30) binds the truss securely at the standoff anchor base (64). The sandwiching of the standoff anchor (18), truss (60) and the windshield (28) binds the truss (65) at the top of the standoff anchor (60). The result is a support for the span of the windshield (28) that does not interfere with windshield (28) contraction and expansion.

FIG. 10 illustrates a unique aeration heater (50) that uses aeration to heat a pool or any water source, in accordance with one embodiment of the present invention. The aeration heater (50) fills with water to weigh down the unit even with air flow. The base can also be filled with sand or other heavy material to the water level (54). This will keep the aeration heater (50) submerged when air is injected. Air is injected through an air inlet (53) and is released in the water as fine hot air bubbles through the minute orifices (55). Heat transfer from bubbles to water is strictly conductive. This is a very low cost but unique solution to the expensive, high energy consuming heat exchangers.

FIG. 11 illustrates a duct booster assembly (13) which has an electric AC motor (59) that is plug-in ready, in accordance with one embodiment of the present invention. A regular electric cord and plug (58) powers this unit without the need for an electrician. The duct booster assembly (13) has a temperature sensor switch (57) that can be positioned at any location in the hot air exhaust tube (10). The hot air that is being pushed down from the solar collector (3) by the photovoltaic powered blower assemblies (20) trigger the temperature sensor (57) and activate the electric AC motor (59). The fan blades (60) can then thrust the hot air through the duct work (12) to heat the house (1). A house thermostat (56) can be set to limit house heat at a preset temperature. The advantage of this is that the duct booster assembly (13) is completely automatic, turning on and off based on deliverable usable hot air from the solar panel (3). It is understood that in Northern climates the temperature outside may be 20 below zero on a sunny day and the solar collector (3) may only raise the temperature to 60 degrees Fahrenheit. The duct booster assembly (13) would not activate in this scenario because the usable hot air preset temperature is 70.5 degrees and 60 degrees would cool the house down. Again this emphasizes the advantage of using a heat pump (73), married to a solar collector (3) for maximum advantage at much lower temperatures. The duct booster assembly can also be used to pre-heat the fresh air intake to the building. Most buildings houses, hospitals, apartment buildings as an example require fresh air verses re-circulating indoor polluted air. The solar collector with booster assembly can pre-heat fresh outdoor air making the indoor heating system more efficient.

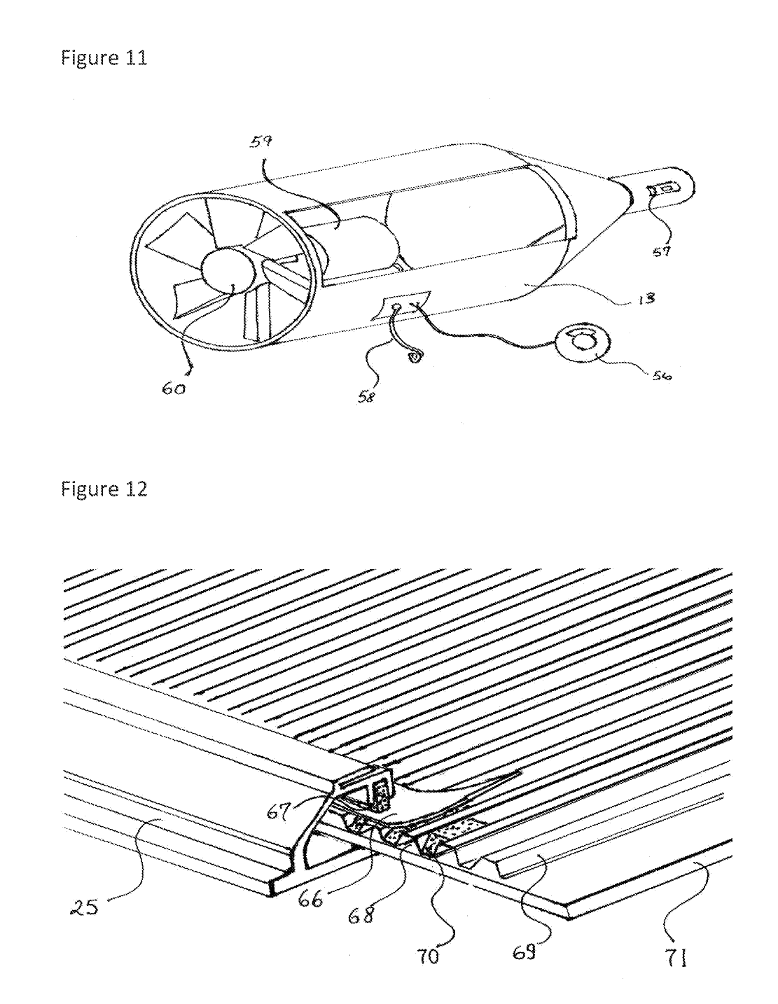

FIG. 12 illustrates the unique design advantage of the aluminum version of this solar collector, in accordance with one embodiment of the present invention. With the plastic corrugated solar collector the corrugations (30) and base are plastic welded together in a single continuous action. With the aluminum version the aluminum corrugations (69) are adhered to a closed cell foam base (71). The closed cell foam base (71) creates the air seal and insulates the air and aluminum from the roof surface (2). To seal the air where the re-directional bracket (25) meets the aluminum corrugations (69), a rubberized filler (70) is inserted between the aluminum ribs (68) to a width of approximately 1 inch. Covering the corrugated ribs (68) and rubberized seal (70) is a 2 inch strip of plastic or foam material (66). This 2 inch strip (66) acts as a flat surface for the closed cell foam seal (67) to slide upon during expansion and contraction of aluminum. In this manner the foam seal (67) does not require the matching teeth (26) that are present in the plastic version. Using this configuration the aluminum corrugations (69) can still be rolled up for shipping purposes in unlimited lengths, which is a key feature of the overhaul invention. The aluminum corrugation (69) is rated amongst the most conductive of heat and when combined with the insulation gain of closed cell base (71) renders this invention highly efficient. This design will cost more per square foot, however it also has unique advantages.

The base of the solar collector is made of single-sided corrugated plastic material. This material comes in rolls and can be cut to length. It is ideal for passing air through the interior and for absorbing solar heat. The result is with the right configuration the material can be used to create a low cost solar hot air generator. To achieve maximum result and complete surface coverage of material, a criss-cross system was designed for the material. The air flows into the corrugation through a 12 inch blower intake. The air then crosses through the 12 inch wide corrugation to the opposing side. On the opposing side a 24 inch bracket accepts the air flow from the first 12 inch blower and directs the air to the second half of the 24 inch bracket. The air travels down the second 12 inches to another 24 inch bracket where the process repeats until the end of the corrugation, where it exits hot from another 12 inch blower. Placing of more blower units at various intervals allows air flow and heat transfer in longer continuous lengths. The blowers also guaranty a relatively equal volume of air to all segments of the corrugation regardless of the configuration of the solar panels. Whether the panels are configured in series, parallel or combinations of series and parallel the air flow is equal throughout. A high powered booster fan can be hardwired to the house electrical system to assure sufficient air flow for house consumption. Using only the booster fan or any single suction or pushing fan would result in air flow through the path of least resistance. Therefore areas of the solar collector would be neglected or receive minimal flow. The initial blower unit that begins the air flow is a unique design that incorporates a blower motor that is powered by solar photovoltaic cells. The advantage is that the blower activates when the sun hits the photovoltaic cells. This is ideal in that the same sun is now heating the corrugated plastics. This simplicity reduces initial cost and future maintenance cost. No need for complex sensors, or external power required. This eliminates the needs for expensive electricians that are required with other systems. The exit blower is also powered by its own solar photovoltaic cells. This system can also continue to another corrugated sheet as often as required.

The corrugated plastic sheets are anchored to a roof or other solid surface via fasteners at the center of the sheet at every predetermined interval that is equal to the width of the blower assembly and half the width of the deflection bracket. These locations are imprinted in the manufacturing process to seal the air flow and simplify installation. Centering the anchoring system also allows for linear expansion of corrugated material towards the deflection brackets. The brackets are designed to seal while allowing the corrugation movement for expansions and contractions. Any expansion of material towards the ends is absorbed in the corrugation by simply allowing the individual ribs to contract in and rise up. The anchoring system also anchors the top clear plastic sheet to the roof at its second level. This clear plastic sheet anchoring system also allows for clear plastic material to expand and contract with waving or other stress concerns. The brackets on the sides are designed to redirect the air flow in the cross-over pattern. Each bracket is comprised of a single extrusion of plastic with incorporated claws that hold the closed cell foam teeth. At the top of the extrusion is an over-hang lip that is designed to clamp the clear plastic sheet tightly while allowing the sheet to expand in and contract out. The extrusion also incorporates a base plate that extends beyond the front sufficient to secure the corrugated plastic while the top part of the bracket can be bent up to ease insertion of the corrugated plastic under foam teeth. Release of the top of the bracket than applies sufficient force to seal air within the bracket interior and corrugation interior. The base of the bracket also extends past the cavity sufficient in distance to accommodate an anchor, screw or other fastener. Fasteners are to be located in the center of the bracket to allow for a secure hold in all wind conditions. Anchors can be located at the end of the brackets provided as long as they are not tightened to the point where they impede movement.

While the present invention has been related in terms of the foregoing embodiments, those skilled in the art will recognize that the invention is not limited to the embodiments described. The present invention can be practiced with modification and alteration within the spirit and scope of the appended claims. Thus, the description is to be regarded as illustrative instead of restrictive on the present invention.

What is claimed is:

1. A single face corrugated plastic solar collector device to heat a designated area or piece of equipment that is attached to an attachment surface, comprising:
a plurality of solar collectors with sides, individual corrugations, redirection brackets with a center and a criss-cross intake air flow pattern for absorbing solar energy from a solar source, such as the sun and converting said solar energy into heat;
a blower assembly for blowing and dispersing intake air through said solar panel;
a photovoltaic assembly that powers said blower assembly; and
a duct fan assembly that distributes exhaust air once it leaves said blower panels to its desired destination.

2. The device according to claim 1, wherein said solar collectors are configured in series, parallel or a combination of series and parallel configurations.

3. The device according to claim 1, wherein said individual corrugations and said redirection brackets are located at said sides of solar collectors to facilitate said criss-cross intake air flow pattern.

4. The device according to claim 3, wherein said redirection brackets are attached to said attachment surface by a screw placed in said center of said redirection brackets.

5. The device according to claim 1, wherein a glazing covers and encloses each individual said plurality of solar collectors.

6. The device according to claim 5, wherein said glazing is attached to said individual panel with a standoff fastener that includes a screw, a truss and a retaining lip.

7. The device according to claim 1, wherein a corrugated tooth seal seals and insulates said individual corrugations and any adjacent cavities and is held in place by an inside cavity tooth support and an outside cavity tooth support.

8. The device according to claim 1, wherein a first blower fan blows intake aft throughout said criss-cross pattern.

9. The device according to claim 1, wherein said individual corrugations are supported by an extended base.

10. The device according to claim 9, wherein said individual corrugations are adhered to said extended base that gain conductivity and insulation, while retaining ability to be rolled in unlimited lengths.

11. The device according to claim 1, wherein redirection booster fan blowers assist said first blower in blowing said intake air throughout said criss-cross pattern.

12. The device according to claim 11, wherein said redirection booster fan blowers have a house thermostat switch, a temperature sensor, an electric cord and plug, an electric AC motor and a plurality of fan blades.

13. The device according to claim 1, wherein said intake air is stopped by a redirection bracket seal that stops airflow through said redirection brackets and to a plurality of aft cut-outs.

14. The device according to claim 1, wherein sad intake air is redirected to said duct fan assembly through said plurality of air cut-outs and a blower cover.

15. The device according to claim 1, wherein said photovoltaic assembly has a plurality of photovoltaic cells, a plurality of photovoltaic panels, a photovoltaic cover and a solstice hinge.

16. The device according to claim 1, wherein said desired destinations and said designated area or piece of equipment are a house, a pool, a hot tub, a pre-heat fresh of intake for duct work, building heat a heat pump and a clothes dryer.

17. The device according to claim 16, wherein said exhaust air is distributed to said pool through pool tubing.

18. The device according to claim 17 wherein said exhaust aft is distributed from said pool tubing to an aeration heater.

19. The device according to claim 16, wherein said exhaust aft is distributed to said clothes dryer through dryer tubing and said hot tub through hot tub tubing.

20. The device according to claim 1, wherein said device is made of aluminum or plastic.
